(19) United States
(12) Patent Application Publication
(10) Pub. No.: US 2024/0063240 A1
(43) Pub. Date: Feb. 22, 2024

(54) LIGHT STATE IMAGING PIXEL

(71) Applicant: SONY SEMICONDUCTOR SOLUTIONS CORPORATION, Kanagawa (JP)

(72) Inventor: Victor A. Lenchenkov, Rochester, NY (US)

(73) Assignee: SONY SEMICONDUCTOR SOLUTIONS CORPORATION, Kanagawa (JP)

(21) Appl. No.: 17/890,428

(22) Filed: Aug. 18, 2022

(51) Int. Cl. H01L 27/146; G02B 27/42; H04N 5/369

(52) U.S. Cl. CPC H01L 27/14625; G02B 27/4205; H04N 5/379

(57) ABSTRACT

Light state image sensors and systems are provided. The light state image sensor includes a plurality of pixels, each of which includes a plurality of sub-pixels. A diffraction layer is disposed adjacent a light incident surface side of the array includes a set of electrically conductive or semiconductive diffraction features for each pixel. Each set of diffraction features includes linear elements disposed along different radii extending from a centerline of the respective pixel. Non-linear scattering elements can also be included in each set of diffraction features. Light state information, such as color and polarization state, of light incident on a pixel is determined by comparing ratios of signals between pairs of sub-pixels to values stored in a calibration table.

### FIELD

The present disclosure relates to an imaging device incorporating an interference enhanced diffractive grating to enable the identification of incident light states.

### BACKGROUND

Digital image sensors are commonly used in a variety of electronic devices, such as handheld cameras, medical devices, security systems, telephones, computers, and tablets, to capture images. In a typical arrangement, light sensitive areas or pixels are arranged in a two-dimensional array having multiple rows and columns of pixels. Each pixel generates an electrical charge in response to receiving photons as a result of being exposed to incident light. For example, each pixel can include a photodiode that generates charge in an amount that is generally proportional to the amount of light (i.e. the number of photons) incident on the pixel during an exposure period. The charge can then be read out from each of the pixels, for example through peripheral circuitry.

In conventional color image sensors, absorptive color filters are used to enable the image sensor to detect the color of incident light. The color filters are typically disposed in sets (e.g. of red, green, and blue (RGB); cyan, magenta, and yellow (CMY); or red, green, blue, and infrared (RGBIR)). Such arrangements have about 3-4 times lower sensitivity and signal to noise ratio (SNR) at low light conditions, color crosstalk, color shading at high chief ray angles (CRA), and lower spatial resolution due to color filter patterning, resulting in lower spatial frequency as compared to monochrome sensors without color filters. However, the image information provided by a monochrome sensor does not include information about the color of the imaged object.

In addition, conventional color and monochrome image sensors incorporate non-complementary metal-oxide semiconductor (CMOS), polymer-based materials, for example to form filters and micro lenses for each of the pixels, that result in image sensor fabrication processes that are more time-consuming and expensive than processes that only require CMOS materials. Moreover, the resulting devices suffer from compromised reliability and operational life, as the included color filters and micro lenses are subject to weathering and performance that degrades at a much faster rate than inorganic CMOS materials. In addition, the processing required to interpolate between pixels of different colors in order to produce a continuous image is significant.

Image sensors have been developed that utilize uniform, non-focusing metal gratings or grids, that attenuate light outside of a selected polarization direction, before that light is absorbed in a silicon substrate. Such an approach enables the polarization characteristics of incident light to be determined, without requiring the use of absorptive filters. However, the non-focusing diffractive grating results in light loss before the light reaches the substrate. As a result, the quantum efficiency of such sensors in very low. Such an approach also requires an adjustment or shift in the microlens and the grating position and structures across the image plane to accommodate high chief ray angles (CRAs).

Accordingly, it would be desirable to provide an improved image sensor that was capable of sensing characteristics of incident light, including the color and polarization state of the light.

### SUMMARY

Embodiments of the present disclosure provide image sensors, image sensing methods, and methods for in-pixel interferometric recording of an image of a light field using diffractive grating and scattering elements, referred to herein as diffractive elements. The provided interferometric imaging enables information about the light field (light state) incident at the pixels to be determined. Characteristics of the light that can be decoded by embodiments of the present disclosure include color or spectral information; polarization; phase; divergence; and super-resolution information. Such information can be obtained in connection with conventional imaging operations, or in connection with imaging complex light fields and their characteristics.

An image sensor in accordance with embodiments of the present disclosure includes a plurality of pixels disposed across an imaging surface. Each of the pixels includes a plurality of sub-pixels. A diffraction layer is disposed adjacent a light incident surface side of the image sensor. The diffraction layer includes a set of electrically conductive or semi-conductive diffraction elements or features for each pixel in the plurality of pixels. The diffraction features scatter incident light onto the sub-pixels. The diffraction pattern produced across the area of the pixel by the diffraction features is dependent on the light state of the incident light. For example, the light state measured or determined by embodiments of the present disclosure can include the wavelength, polarization state, phase and amplitude of incident light. In accordance with the least some embodiments of the present disclosure, the light state of the light incident on a pixel can be determined from ratios of relative signal intensities at each of the sub-pixels within the pixel. Accordingly, embodiments of the present disclosure provide an image sensor that does not require color filters in order to identify the wavelength of incident light. In addition, embodiments of the present disclosure do not require micro lenses or infrared filters in order to provide high resolution images and high resolution color identification. Furthermore, embodiments of the present disclosure provide an image sensor that can determine a polarization state of incident light from ratios of relative signal intensities at each of the sub-pixels within the pixel. Because embodiments of the present disclosure allow the polarization state to be determined from the scattering of light achieved by the included scattering elements, without requiring the use of polarization grids, sensitivity and resolution can be improved as compared to conventional polarization sensing devices. The resulting light state image sensor has high sensitivity, high spatial resolution, high color resolution, wide spectral range, the ability to detect a number of linear and circular polarization states, the ability to detect the phase of incident light, a low stack height, and can be manufactured using conventional CMOS processes.

An imaging device or apparatus in accordance with embodiments of the present disclosure incorporates an image sensor having a diffraction layer on a light incident side of a sensor substrate. The sensor substrate includes an array of pixels, each of which includes a plurality of light sensitive areas or sub-pixels. The diffraction layer includes a set of electrically conductive or semi-conductive diffraction features for each pixel. The diffraction features can include linear elements particularly configured for the detection of different light polarizations. In accordance with the least some embodiments of the present disclosure, the linear elements are disposed to extend radially from a centerline of the associated pixel, and increase in length from one line to the next in one of a clockwise or anticlockwise direction. The diffraction features can additionally include scattering elements. In accordance with the least some embodiments of the present disclosure, the diffraction features are sized such that an area of each sub-pixel covered by the diffraction features is the same or about the same. Accordingly, the diffraction features operate as diffractive pixel micro lenses, which create asymmetric diffractive light patterns that are strongly dependent on the color and polarization of incident light. Because the diffraction layer is relatively thin (e.g. about 500 nm or less), it provides a very high coherence degree for the incident light, which facilitates the formation of stable interference patterns.

The relative distribution of the incident light amongst the sub-pixels of a pixel is determined by comparing the signal ratios. For example, in a configuration in which each pixel includes a 2×2 array of sub-pixels, there are 6 possible combinations of sub-pixel signal ratios that can be used to identify the color of light incident at the pixel with very high accuracy. In particular, because the interference pattern produced by the diffraction elements strongly correlates with the color and polarization of the incident light, the incident light color and polarization can be identified with very high accuracy (e.g. within 25 nm or less). The identification or assignment of the color and polarization of the incident light from the ratios of signals produced by the sub-pixels can be determined by comparing those ratios to pre-calibrated sub-pixel photodiode signal ratios (attributes) for different light states, such as color and polarization, of incident light.

An imaging device or apparatus incorporating an image sensor in accordance with embodiments of the present disclosure can include an imaging lens that focuses collected light onto an image sensor. The light from the lens is focused and diffracted onto pixels included in the image sensor by electrically conductive or semi-conductive diffraction features. More particularly, each pixel includes a plurality of sub-pixels, and is associated with a set of diffraction features. The diffraction features function to create an asymmetrical diffraction pattern across the sub-pixels. Differences in the strength of the signals at each of the sub-pixels within a pixel can be applied to determine a light state of the light incident on the pixel.

Imaging sensing methods in accordance with embodiments of the present disclosure include focusing light collected from within a scene onto an image sensor having a plurality of pixels disposed in an array. The light incident on each pixel is focused and diffracted by a set of diffraction features onto a plurality of included sub-pixels. The diffraction pattern produced by the diffraction features depends on the light state of the incident light. Accordingly, the amplitude of the signal generated by the incident light at each of the sub-pixels in each pixel can be read to determine the light state of that incident light. In accordance with embodiments of the present disclosure, the assignment of a light state to light incident on a pixel includes determining ratios of signal strengths produced by sub-pixels within the pixel, and comparing those ratios to values stored in a lookup table for light state assignment. An image sensor produced in accordance with embodiments of the present disclosure therefore does not require micro lenses for each pixel or color filters, and provides high light state sensitivity over a range of wavelengths that can be coincident with the full wavelength sensitivity of the image sensor pixels.

Additional features and advantages of embodiments of the present disclosure will become more readily apparent from the following description, particularly when considered together with the accompanying drawings.

### BRIEF DESCRIPTION OF THE DRAWINGS

FIG. 1 depicts elements of a light state image sensor in accordance with embodiments of the present disclosure;

FIG. 2 is a view in cross section of a portion of a pixel array of an exemplary color and polarization sensing image sensor in accordance with the prior art;

FIG. 3 is a plan view of a portion of a pixel array of the exemplary color and polarization sensing image sensor of FIG. 2, and in particular illustrates a portion of a polarization grid layer of the image sensor;

FIG. 4 is a plan view of a portion of a pixel array of the exemplary color and polarization sensing image sensor of FIG. 2, and in particular illustrates a color filter array layer of the image sensor;

FIG. 5 depicts components of a system incorporating a light state image sensor in accordance with embodiments of the present disclosure;

FIG. 6 is a perspective view of a pixel included in a light state image sensor in accordance with embodiments of the present disclosure;

FIG. 7 is a plan view of the pixel of FIG. 6;

FIG. 8 is a cross section in elevation of a pixel configuration in accordance with embodiments of the present disclosure;

FIG. 9 depicts the diffraction of light by a set of diffractive and scattering elements across the sub-pixels of a pixel included in a light state image sensor in accordance with embodiments of the present disclosure;

FIG. 10 depicts an example of a pre-calibrated light state vector matrix or table of signal ratio values for different wavelengths and polarizations of light incident on the sub-pixels of a pixel included in a light state image sensor in accordance with embodiments of the present disclosure;

FIG. 11 depicts aspects of a process for determining light state information of light incident on an example pixel included in a light state image sensor in accordance with embodiments of the present disclosure;

FIG. 12 depicts an exemplary set of measured signal ratios obtained from a pixel included in a light state image sensor in accordance with embodiments of the present disclosure entered into a measured light state vector matrix;

FIG. 13 depicts a table of calculated difference values obtained by finding a difference between the values in the pre-calibrated light state vector matrix and the values in the measured light state vector matrix for an example pixel in accordance with embodiments of the present disclosure; and

FIG. 14 is a block diagram illustrating a schematic configuration example of a camera that is an example of an image sensor in accordance with embodiments of the present disclosure.

### DETAILED DESCRIPTION

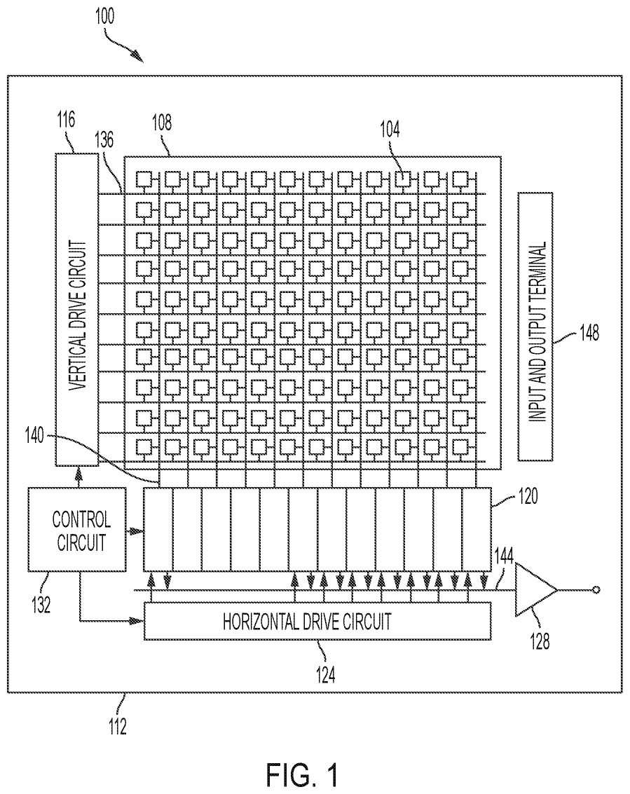

FIG. 1 is a diagram that depicts elements of a light state image sensor or device 100 in accordance with embodiments of the present disclosure. In general, the light state image sensor 100 includes a plurality of pixels 104 disposed in an array 108. More particularly, the pixels 104 can be disposed within an array 108 having a plurality of rows and columns of pixels 104. Moreover, the pixels 104 are formed in an imaging or semiconductor substrate 112. In addition, one or more peripheral or other circuits can be formed in connection with the imaging substrate 112. Examples of such circuits include a vertical drive circuit 116, a column signal processing circuit 120, a horizontal drive circuit 124, an output circuit 128, and a control circuit 132. As described in greater detail elsewhere herein, each of the pixels 104 within a light state image sensor 100 in accordance with embodiments of the present disclosure includes a plurality of photosensitive sites or sub-pixels.

The control circuit 132 can receive data for instructing an input clock, an operation mode, and the like, and can output data such as internal information related to the image sensor 100. Accordingly, the control circuit 132 can generate a clock signal that provides a standard for operation of the vertical drive circuit 116, the column signal processing circuit 120, and the horizontal drive circuit 124, and control signals based on a vertical synchronization signal, a horizontal synchronization signal, and a master clock. The control circuit 132 outputs the generated clock signal in the control signals to the various other circuits and components.

The vertical drive circuit 116 can, for example, be configured with a shift register, can operate to select a pixel drive wiring 136, and can supply pulses for driving sub-pixels of a pixel 104 through the selected drive wiring 136 in units of a row. The vertical drive circuit 116 can also selectively and sequentially scan elements of the array 108 in units of a row in a vertical direction, and supply the signals generated within the pixels 104 according to an amount of light they have received to the column signal processing circuit 120 through a vertical signal line 140.

The column signal processing circuit 120 can operate to perform signal processing, such as noise removal, on the signal output from the pixels 104. For example, the column signal processing circuit 120 can perform signal processing such as a correlated double sampling (CDS) for removing a specific fixed patterned noise of a selected pixel 104 and an analog to digital (A/D) conversion of the signal.

The horizontal drive circuit 124 can include a shift register. The horizontal drive circuit 124 can select each column signal processing circuit 120 in order by sequentially outputting horizontal scanning pulses, causing each column signal processing circuit 122 to output a pixel signal to a horizontal signal line 144.

The output circuit 128 can perform predetermined signal processing with respect to the signals sequentially supplied from each column signal processing circuit 120 through the horizontal signal line 144. For example, the output circuit 128 can perform a buffering, black level adjustment, column variation correction, various digital signal processing, and other signal processing procedures. An input and output terminal 148 exchanges signals between the image sensor 100 and external components or systems.

Accordingly, a light state image sensor 100 in accordance with at least some embodiments of the present disclosure can be configured as a CMOS image sensor of a column A/D type in which column signal processing is performed.

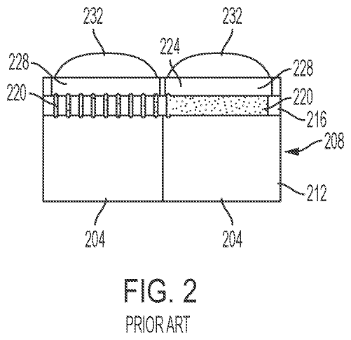

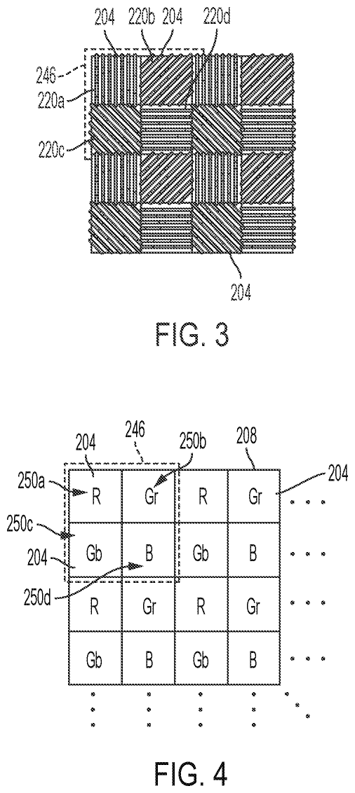

With reference now to FIGS. 2, 3 and 4, portions of a pixel array 208 of an exemplary image sensor capable of sensing a color and polarization state of incident light in accordance with the prior art are depicted. More particularly FIG. 2 depicts a portion of the pixel array 208 in a cross section view. Each pixel 204 within the pixel array 208 can include a photodiode formed in a semiconductor layer 212. A polarization grid layer 216, containing different polarization grid patterns 220, is disposed on or adjacent a light incident surface of the semiconductor layer 212. A color filter layer 224, including different color filters 228, is disposed on or adjacent a light incident surface of the polarization grid layer 220. In addition, each pixel 204 can be associated with a microlens 232. As shown in FIGS. 3 and 4, individual pixels 204 within the pixel array 208 are disposed in 2×2 sets 246 of four pixels 204. Each pixel 204 within a set 246 is associated with a different pixel grid pattern 220. For instance, a first pixel 204 is overlayed by a vertical pixel grid pattern 220a, a second pixel 204 is overlayed by a first diagonal pixel grid pattern 220b, the third pixel 204 is overlayed by a second diagonal pixel grid patterns 220c, wherein a direction of the first diagonal pixel grid pattern is orthogonal to the direction of the second diagonal pixel grid pattern, and the fourth pixel 204 is overlayed by a horizontal pixel grid pattern 220d. Thus configured, signals from the pixels 204 within each set 246 of pixels allows a polarization direction of incident light to be discerned. With particular reference now to FIG. 4, each of the pixels 204 within a set 246 is also associated with a color filter 250. In this particular example, each 2×2 set 246 of four pixels 204 is configured as a so-called Bayer array, in which a first one of the pixels 204 is associated with a red color filter 250a, a second one of the pixels 204 is associated with a green color filter 250b, a third one of the pixels 204 is associated with another green color filter 250c, and a fourth one of the pixels 204 is associated with a blue color filter 250d. From the signals of the individual pixels 204 within a set 246, the color of the incident light can be discerned. In such a configuration, each individual pixel 204 is primarily sensitive to light having a polarization that is about perpendicular to the grid lines of the associated grid patterns 220, and is only sensitive to a portion of the visible spectrum. As a result, spatial resolution is lost. In addition to the various performance issues, conventional color and polarization sensing image sensors have a relatively high stack height, and typically incorporate non-CMOS polymer-based materials, which adds costs to the manufacturing process, and results in a device that is less reliable and that has a shorter lifetime, as color filters and micro lenses are subject to weathering and to performance that degrades more quickly than inorganic CMOS materials.

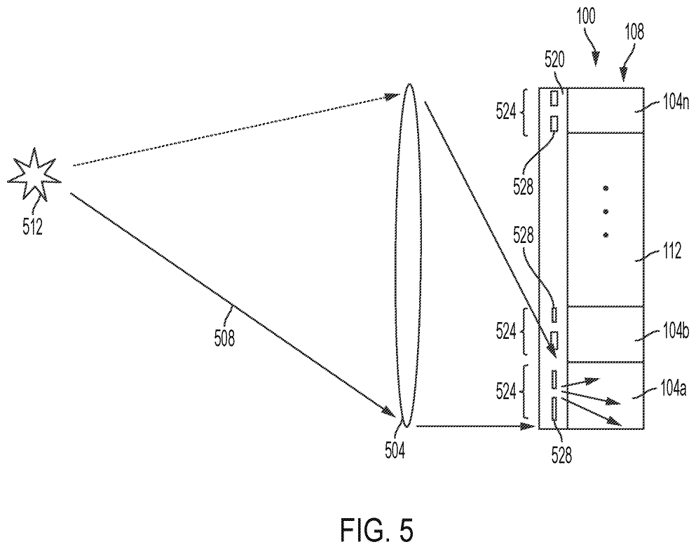

FIG. 5 depicts components of a system 500 incorporating a light state image sensor 100 in accordance with embodiments of the present disclosure. As shown, the system 500 can include an optical system 504 that collects and focuses light from within a field of view of the system 500, including light 508 reflected or otherwise received from an object 512 within the field of view of the system 500, onto the pixel array 108 of the image sensor 100. As can be appreciated by one of skill in the art after consideration of the present disclosure, the optical system 504 can include a number of lenses, apertures, shutters, filters or other elements. In accordance with embodiments of the present disclosure, the pixel array 108 includes an imaging or sensor substrate 112 in which the pixels 104 of the array 108 are formed. In addition, a diffraction layer 520 is disposed on a light incident surface side of the substrate 112, between the pixel array 108 and the optical system 504. The diffraction layer 520 includes a plurality of electrically conductive or semiconductive diffraction features or elements 524. More particularly, the diffraction features or elements 528 are provided as sets 524 of diffraction features 528, with one set 524 of diffraction features 528 being provided for each pixel 104 of the array 108.

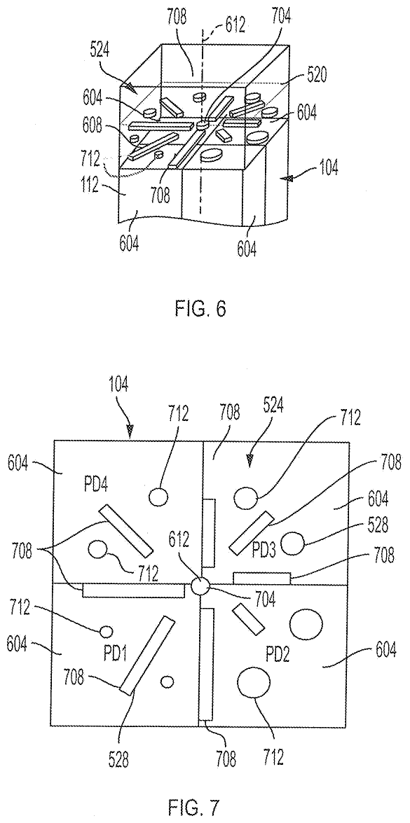

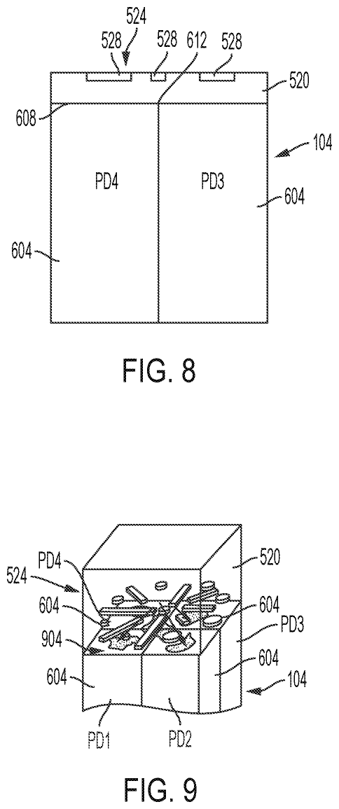

With reference now to FIGS. 6-8, a pixel 104 of a light state image sensor 100 in accordance with embodiments of the present disclosure is depicted in a variety of views. More particularly, FIG. 6 is a perspective view of a pixel 104 included in a light state image sensor 100 in accordance with embodiments of the present disclosure; FIG. 7 is a plan view of the pixel 104; and FIG. 8 is a cross section in elevation of a pixel 104 in accordance with embodiments of the present disclosure.

Each pixel 104 in a light state image sensor 100 in accordance with embodiments of the present disclosure includes a plurality of sub-pixels 604. The sub-pixels 604 within a pixel 104 generally include adjacent photoelectric conversion elements or areas within the image sensor substrate 112. In operation, each sub-pixel 604 generates a signal in proportion to an amount of light incident thereon. As an example, each sub-pixel 604 is a photodiode. As represented in FIGS. 6, 7, and 8, each pixel 104 can include four sub-pixels 604, with each of the sub-pixels 604 having an equally sized, square-shaped light incident surface 608. However, embodiments of the present disclosure are not limited to such a configuration, and can instead have any number of sub-pixels 604, with each of the sub-pixels 604 having the same or different shape, and/or the same or different size, as other sub-pixels 604 within the pixel 104. In accordance with at least some embodiments of the present disclosure, each of the pixels 104 within the light state image sensor have the same sub-pixel 604 configuration. In addition, each sub-pixel 604 within a pixel 104 can have the same sensitivity.

As previously discussed, each pixel 104 is associated with a set of diffraction features or elements 524. The diffraction elements 528 within a set 524 can be centered on a line or axis that is perpendicular to the light incident surface of the image sensor 100, and that is coincident with or parallel to a centerline 612 extending from the geometric center of the light incident area of the pixel 104. In accordance with further embodiments of the present disclosure, the diffraction features 528 within a set 524 can be centered along a line that extends from the center of the pixel 104 area, and that follows or is parallel to a chief ray angle associated with the relevant pixel 104. In accordance with the least some embodiments of the present disclosure, the set of diffraction features 524 associated with a pixel 104 include a central feature 704 that is centered on or adjacent the centerline 612 of the pixel 104. As an example, but without limitation, the central feature 704 can be configured as a cylindrical element. Moreover, the centerline 612 associated with the pixel 104 area and the central feature 704 can be disposed on or adjacent a line intersecting a point that is centered between the light incident surfaces 608 of the sub-pixels 604.

In accordance with embodiments of the present disclosure, the set of diffraction features 524 includes a number of elongated or linear elements 708. As examples, but without limitation, the linear elements 708 are configured in a rectangular shape. In accordance with embodiments of the present disclosure, the linear elements 708 are disposed along or parallel to lines extending radially from the centerline 612 of the pixel 104 when the pixel 104 is seen in a plan view. In accordance with embodiments of the present disclosure, the radially extending linear elements 708 can be disposed at equal intervals about the centerline 612. For example, but without limitation, and as illustrated in FIGS. 6-8, the set of diffraction elements 524 can include eight linear elements 708 disposed 45 degrees apart from each neighboring linear element 708. In addition, each linear element 708 within a set of diffraction elements 524 can have a length that is different than every other linear element 708 within that set 524. In accordance with at least some embodiments of the present disclosure, the length of the linear elements 708 increases, moving around the circle, from a shortest linear element 708 to a next shortest linear element 708 and so on until the longest linear element 708 is reached. Then, continuing in the same direction, the shortest linear element 708 will again be encountered. This gradual increase in length can be implemented in either a clockwise or an anti-clockwise direction. In accordance with embodiments of the present disclosure, the linear elements 708 are relatively thin, in that they have a narrow width as compared to their length. For instance, a linear element 708 can have a length to width ratio of greater than 5:1. As another example, a linear element 708 can have a length to width ratio of from 5:1 to 1000:1.

In accordance with still further embodiments of the present disclosure, the sets of diffraction elements 524 can also include a plurality of scattering elements 712. The scattering elements 712 can be configured similarly to the central element 704. Accordingly, as an example, each scattering element 712 can be configured as a cylinder, with the ends of the cylinder parallel to the light incident surface of the pixel 104. The scattering elements 712 can be disposed in areas generally between adjacent linear elements 708. For instance, and as illustrated in FIG. 7, scattering elements 712 can be disposed at locations intersected by radial lines extending from the centerline 612 of the pixel 104 that are separated from one another by 45 degrees (and that are separated from radial lines along which neighboring linear elements 708 are disposed by 22.5 degrees). In accordance with at least some embodiments of the present disclosure, the light incident areas of the scattering elements 712 are sized such that, in combination with the light incident areas of the linear elements 708, the total area of the elements 528 over any one sub-pixel 604 within a pixel 104 is the same as for any other sub-pixel 604 within that pixel 104. In such a configuration, where the length of the linear elements 708 increases in a one direction, the diameter of cylindrical scatter elements 712 will increase in the opposite direction. Moreover, in accordance with embodiments of the present disclosure, the area of the diffraction elements 528 over any one sub-pixel 604 is a small (e.g. <20%) proportion of the light sensitive area of the sub-pixel 604.

With reference now to FIG. 8, a pixel 104 in accordance with embodiments of the present disclosure is shown in cross-section, along section line taken through the centerline 612. In accordance with embodiments of the present disclosure, the diffraction layer 520 can be formed of low index SiO2, having a refractive index (n) that is about equal to 1.46, while the diffraction elements 528 can be formed using electrically conductive materials. Examples of suitable materials for the diffraction elements 528 include, but are not limited to, aluminum, tungsten, or other metals. In accordance with further embodiments of the present disclosure, the diffraction elements 528 are formed using electrically semi-conductive materials, such as silicon nitride, titanium dioxide, or other semiconductors. In accordance with at least some embodiments of the present disclosure, different diffraction elements 528 within a set of diffraction elements 524 can be formed from the same or different materials. For example, the linear diffraction elements 708 and the central feature 704 can be formed from a high index of refraction semiconductor, and the scattering elements 712 can be formed from strongly scattering, electrically conductive metal material. In accordance with further embodiments of the present disclosure, some or all of the diffraction elements 528 can be formed from a combination of materials, such as a high index semiconductor surrounded by thin (e.g. 5 nm) aluminum metal walls.

As depicted in FIG. 8, the diffraction elements 528 can be formed in the diffraction layer 520 such that they extend from the light incident surface of the diffraction layer 520 towards a light incident surface of the sub-pixels 604. For example, the diffraction elements 528 can have a depth that is less than half a thickness of the diffraction layer 520. The diffraction elements 528 can be formed at the light incident surface of the diffraction layer 520, between the light incident surface and a bottom surface of the diffraction layer 520 adjacent a light incident surface of the sub-pixels 604, or at the bottom surface of the diffraction layer 520. Moreover, different diffraction elements 528 can be formed at different depths within the diffraction layer 520. As examples, but without limitation, for a 1 μm by 1 μm pixel having a 2×2 0.5 μm sub-pixel 604 configuration, the linear diffraction elements 708 can have a length of between 50 nm and 400 nm, a thickness of 50 nm, and a length of between 50 nm and 100 nm. Continuing the foregoing example, the circular or cylindrical scattering elements 712 can have a diameter of between 20 nm and 100 nm, and a thickness of 50 nm. In addition to being configured as regular rectangular or cylindrical elements, diffraction elements 528 can have other shapes. For instance, ends of the elements 528 can be tapered or rounded, a width and/or depth of an element 528 can change over the length of the element, or the like.

The electrically conductive or semiconductive diffraction elements 528 enable the modulation of light amplitude and phase incident on a pixel 104 with a relatively small amount of attenuation. In particular, the attenuation of incident light is much less than in a sensor using a conventional polarization grid. The linear diffraction elements 708 in accordance with embodiments of the present disclosure have their longitudinal axes disposed along lines radiating from the centerline 612 of the pixel 104 that are spaced apart from one another by 45°. As can be appreciated by one of skill in the art after consideration of the present disclosure, light polarized such that its oscillating electric field is parallel to an electrically conductive or semi-conductive material of a linear diffraction element 708 is strongly attenuated. Accordingly, incident light having different polarization states will produce different interference patterns across the sub-pixels 604 of the pixel 104. In addition, the inclusion of scattering elements 712 enables areas of coverage of the diffraction elements 528 with respect to the sub-pixels 604 to be balanced. For example, in accordance with the least some embodiments of the present disclosure, the areas of coverage of the diffraction elements 528 with respect to any one sub-pixel 604 is the same as any other sub-pixel 604 within the pixel 104, ±20%. In accordance with further embodiments of the present disclosure the areas of coverage can be within about ±10% of one another. The combination of a length of linear diffraction elements 708 that changes with radial position about the centerline 612 of the pixel 104, and scattering elements 712 allow additional light states, such as non-linearly polarized light states, to be detected. For example, left and right circularly polarized light will produce different interference patterns, which can be recognized from the different sub-pixel 604 relative signal combinations that will be produced.

The different speckle patterns produced by light interference interactions with the diffraction elements 528 strongly correlates with the illumination conditions, such as light convergence or shape of the incident light wavefront, and can be used to identify the phase state of the light incident on the pixel 104. The decoded phase state of the light can provide possibility of super resolution since it relies on light amplitude interactions recorded as interference patterns rather than light intensity summation (known as Abbe limit for resolution). In addition, the interference pattern will be different for overfocus (light diverging), in focus (light front parallel), or under focus (light converging) states. A representation of the different diffraction patterns or light distribution 904 produced across the different sub-pixels 604 of a pixel 104 by the associated set of diffraction elements 528 is illustrated in FIG. 9. The different distributions of light across the sub-pixels 604 of a pixel 104 produced by the different light states allows the light state incident on the pixel 104 to be determined. The lights states recorded as interference diffraction patterns that can be detected by a light state image senor 100 with pixels 104 configured as disclosed herein can include color (wavelength), polarization, phase dislocation (optical vortex), and singularities (states with different orbital and total angular momentum).

More particularly, the differences in the amount of light incident on the different sub-pixels 604 results in the generation of different signal amounts by those sub-pixels 604. This is illustrated in FIG. 9, which depicts an example distribution of light 904 having a particular state across the sub-pixels 604 of a pixel 104 included in a light state image sensor 100 in accordance with embodiments of the present disclosure. In accordance with embodiments of the present disclosure, the state of the incident light is determined by identifying the unique pattern of that light 904 across the sub-pixels 604 from the resulting sub-pixel 604 pair signal ratios. As can be appreciated by one of skill in the art after consideration of the present disclosure, taking the ratios of the signals from each unique pair of sub-pixels 604 within a pixel 104 allows the distribution pattern 904 to be characterized consistently, even when the intensity of the incident light varies. Moreover, this simplifies the determination of the light state associated with the detected distribution pattern 904 by producing normalized values.

In order to enable the detection of a state of incident light, the pixels 104 included in the image sensor 100 can be calibrated. Calibration can include exposing a pixel 104 to light having a known state, and recording the resulting output from each of sub-pixel 604. For example, where each pixel 104 has the same diffraction element set 524 configuration, the output of the sub-pixels 604 from a single representative pixel 104, the output of the sub-pixels 604 from representative pixels 104 selected from different areas of the image sensor 100, the output of the sub-pixels 604 from randomly selected pixels 104, or the output of the sub-pixels 604 from each pixel 104 within the image sensor 100 can be recorded. As a further example, where different regions or areas of the pixel array 108 have different diffraction element set 524 configurations, an output from the sub-pixels 604 of one or more representative pixels 104 from each area can be recorded. This process can be repeated for each light state of interest.

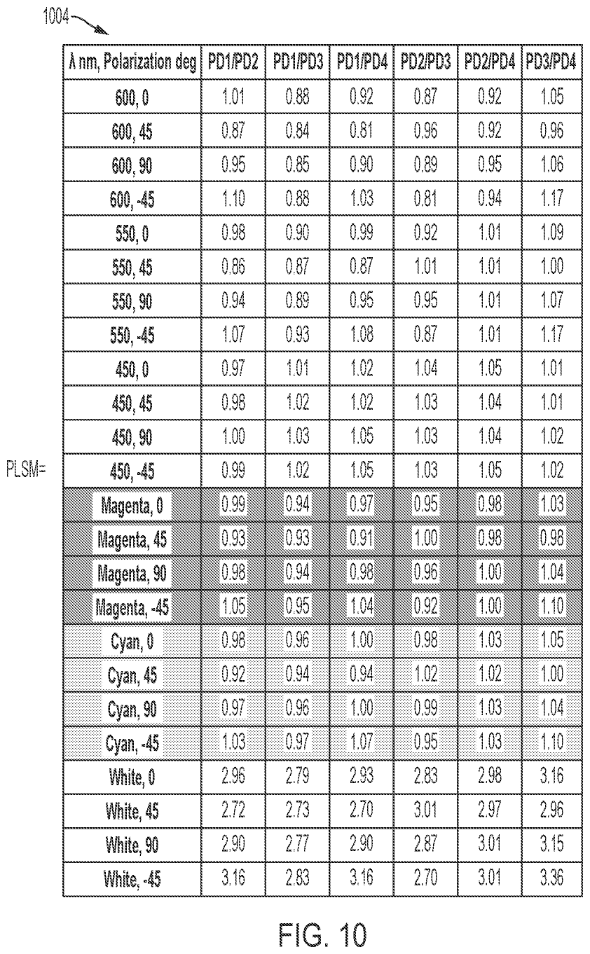

In accordance with embodiments of the present disclosure, ratios of the signal strength or amplitude of the signals produced by pairs of sub-pixels 604 within a pixel 104 are determined. For example, where a pixel 104 includes four sub-pixels 604, six unique sets of sub-pixel 604 amplitudes can be created. In accordance with embodiments of the present disclosure, the values of the ratios between different sub-pixel 604 pairs obtained through the calibration process can be stored in a calibration table 1004, for example as shown in FIG. 10. In this example, the ratios of the signal strength between different pairs of sub-pixels 604 for each of a number of different patterns produced by the different known light states are recorded. Moreover, in this example, the different known light states are wavelength (or color) and polarization angle. As can be appreciated by one of skill in the art after consideration of the present disclosure, signals for additional known light states can be included in a calibration table, thereby enabling the identification of additional light states. For example, the range of wavelengths and the number of wavelengths within a range and the various polarization states that are measured and stored are not limited to any particular number. In addition to identifying additional wavelengths, embodiments of the present disclosure can enable the identification of additional polarization states. For example, in addition to distinguishing polarization states at 0°, 45°, 90°, and minus 45°, a pixel 104 configured in accordance with embodiments of the present disclosure can enable the detection of left hand or right hand circular polarization states. Therefore, at least some embodiments of the present disclosure provide a sensor 100 that can identify six polarization states.

Accordingly, by identifying a light state in a table of different light states associated with sub-pixel 604 signal strength ratios that most closely matches the ratios of signal strengths observed (i.e. measured) for a sample of light of an unknown light state, the light state of the light sample can be accurately assigned. Moreover, identification of the light state of the incident light is possible across a wide range of states. For example, the identification of any wavelength to which the sub-pixels 604 are sensitive is possible. Moreover, a polarization state, including a linear or circular polarization direction, can be detected. For instance, it is possible to provide light state information for light having a wavelength within a range of from 400 nm to 1000 nm, a linear polarization, or a circular polarization. In accordance with embodiments of the present disclosure, an identification of the state of the light incident on a pixel 104 is performed using a simple analytical expression:

Light State Vector=PD1/PD2i−PD1/PD3*j+PD1/PD4*k−PD2/PD*i+PD2/PD4*m−PD3/PD4*n

More particularly, and as shown in the example calibration table 1004, the calibrated light state identification can be stored in a column of color (wavelength) and polarization identification values. Additional columns are provided for tabulating the ratios of the amplitude or intensity of unique pairs of the sub-pixels 604 within the pixel 104 for each light state. As can be appreciated by one of skill in the art after consideration of the present disclosure, the values within the illustrated table 1004 are provided for illustration purposes, and actual values will depend on the particular configuration of the diffraction features 524 and other characteristics of the pixel 104 and associated components of the image sensor 100 as implemented.

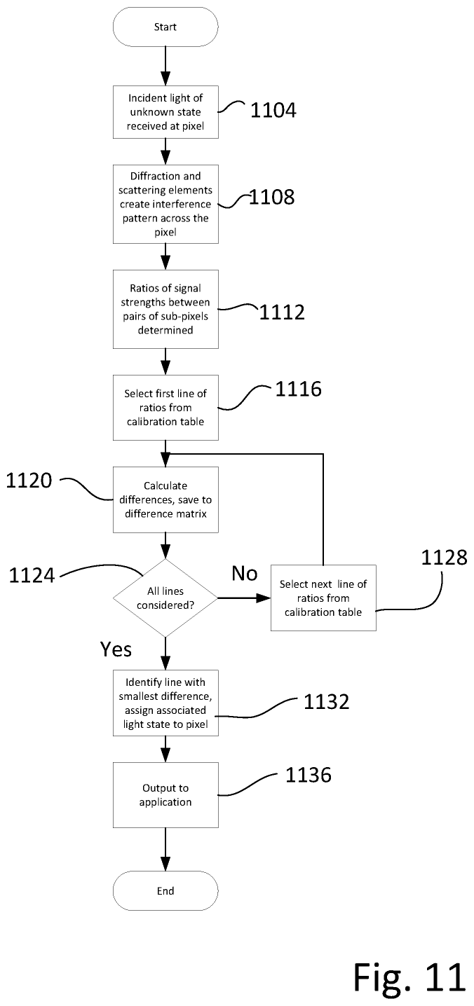

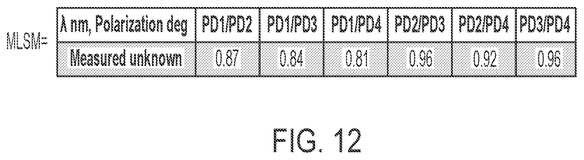

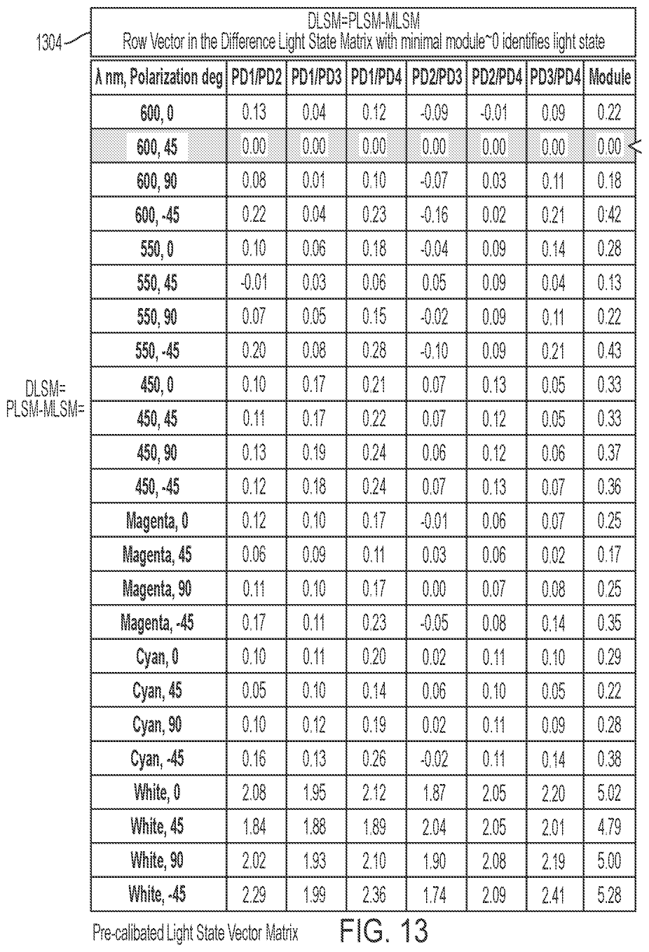

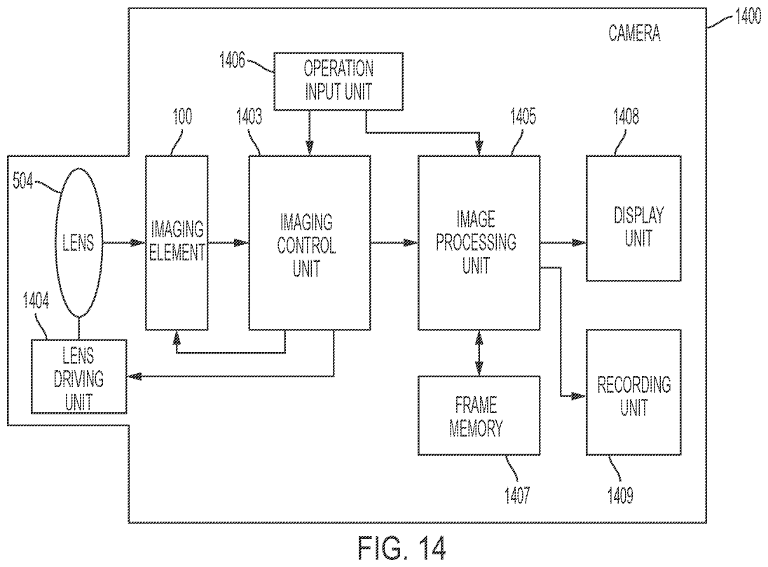

FIG. 11 depicts aspects of a process for assigning and applying a set of measured signal ratios to a calibration table containing signal ratio values for light having different light states to determine the light state of light incident on an example pixel 104. Initially, at step 1104, incident light of an unknown state is received in an area of an image sensor 100 corresponding to a pixel 104. The set 524 of diffraction features 528 associated with the pixel 104 creates an interference pattern across the sub-pixels 604 of the pixel 104 (step 1108). The signals generated by the sub-pixels 604 in response to receiving the incident light are read out, and the ratios of signal strength between pairs of the sub-pixels 604 are determined (step 1112). In particular, the ratio of the signal strength between the two sub-pixels 604 in each unique pair of sub-pixels 604 within the pixel 104 are determined. The results of this determination can themselves be stored in a table, for example a measured unknown table 1204, as shown in FIG. 12. The first line of ratios from the calibration table 1004 is then selected (step 1116). The differences between the ratios stored in the calibration table 1004 and the corresponding ratios determined from the incident light are then calculated and saved to a difference matrix or table 1304 (see FIG. 13)(step 1120). In accordance with embodiments of the present disclosure, the differences for one signal ratio can be calculated as follows:

$$\\ Δ \frac{PD 1}{PD 2} = Calibrated case \frac{PD 1}{PD 2} - Unknown case \frac{PD 1}{PD 2}$$

This calculating and storing of difference values in the difference matrix 1304 is repeated for each ratio represented in the calibration table for the selected wavelength.

At step 1124, a determination is made as to whether all of the lines (i.e. all of the light states) represented within the calibration table 1204 have been considered. If lines remain to be considered, the next line of ratios (corresponding to the next light state) is selected from the calibration table 1004 (step 1128). The ratios measured for the unknown case are then compared to the ratios stored in the table for the next selected line of the calibration table 1004, corresponding to a next calibrated light state, to determine a next set of differences, which are then saved to the difference matrix 1304 (see FIG. 13)(step 1120).

Once all of the lines (light states) of values within the calibration table 1004 have been compared to the measured signal ratios, the line (light state) in the difference matrix 1304 with the smallest row difference is identified, and the associated light state is assigned as the light state of the light incident on the subject pixel 104 (step 1132). Where the difference for one line is zero, the wavelength associated with that line is identified as the light state of the light incident on the subject pixel 104. Where no line has a difference of zero, a row difference for each line is calculated. The row with the smallest calculated row difference value is then selected as identifying the light state of the light incident on the subject pixel. In accordance with embodiments of the present disclosure, the row difference can be calculated as follows:

$$\\ Difference Row Vector Module = \sqrt{{( Δ \frac{PD 1}{PD 2} )}^{2} + {( Δ \frac{PD 2}{PD 3} )}^{2} + … {( Δ \frac{PDn - 1}{PDn} )}^{2}}$$

After the light state of the incident light has been determined, that information can be stored, output to an application, or otherwise utilized. (step 1136). As can be appreciated by one of skill in the art after consideration of the present disclose, this process can be performed for each pixel 104 in the image sensor 100. As can further be appreciated by one of skill in the art after consideration of the present disclosure, where different calibration tables 1004 have been generated for different pixels 104, the process of light state determination is performed in connection with the calibration table 1004 that is applicable to the subject pixel 104.

FIG. 14 is a block diagram illustrating a schematic configuration example of a camera 1400 that is an example of an imaging apparatus to which a system 500, and in particular an image sensor 100, in accordance with embodiments of the present disclosure can be applied. As depicted in the figure, the camera 1400 includes an optical system or lens 504, an image sensor 100, an imaging control unit 1403, a lens driving unit 1404, an image processing unit 1405, an operation input unit 1406, a frame memory 1407, a display unit 1408, and a recording unit 1409.

The optical system 504 includes an objective lens of the camera 1400. The optical system 504 collects light from within a field of view of the camera 1400, which can encompass a scene containing an object. As can be appreciated by one of skill in the art after consideration of the present disclosure, the field of view is determined by various parameters, including a focal length of the lens, the size of the effective area of the image sensor 100, and the distance of the image sensor 100 from the lens. In addition to a lens, the optical system 504 can include other components, such as a variable aperture and a mechanical shutter. The optical system 504 directs the collected light to the image sensor 100 to form an image of the object on a light incident surface of the image sensor 100.

As discussed elsewhere herein, the image sensor 100 includes a plurality of pixels 104 disposed in an array 108. Moreover, the image sensor 100 can include a semiconductor element or substrate 112 in which the pixels 104 each include a number of sub-pixels 604 that are formed as photosensitive areas or photodiodes within the substrate 112. In addition, as also described elsewhere herein, each pixel 104 is associated with a set of diffraction features 524 formed in a diffraction layer 520 positioned between the optical system 504 and the sub-pixels 604. The photosensitive sites or sub-pixels 604 generate analog signals that are proportional to an amount of light incident thereon. These analog signals can be converted into digital signals in a circuit, such as a column signal processing circuit 120, included as part of the image sensor 100, or in a separate circuit or processor. As discussed herein the distribution of light amongst the sub-pixels 604 of a pixel 104 is dependent on the light state of the incident light. The digital signals can then be output.

The imaging control unit 1403 controls imaging operations of the image sensor 100 by generating and outputting control signals to the image sensor 100. Further, the imaging control unit 1403 can perform autofocus in the camera 1400 on the basis of image signals output from the image sensor 100. Here, “autofocus” is a system that detects the focus position of the optical system 504 and automatically adjusts the focus position. As this autofocus, a method in which an image plane phase difference is detected by phase difference pixels arranged in the image sensor 100 to detect a focus position (image plane phase difference autofocus) can be used. Further, a method in which a position at which the contrast of an image is highest is detected as a focus position (contrast autofocus) can also be applied. The imaging control unit 1403 adjusts the position of the lens 1001 through the lens driving unit 1404 on the basis of the detected focus position, to thereby perform autofocus. Note that, the imaging control unit 1403 can include, for example, a DSP (Digital Signal Processor) equipped with firmware.

The lens driving unit 1404 drives the optical system 504 on the basis of control of the imaging control unit 1403. The lens driving unit 1404 can drive the optical system 504 by changing the position of included lens elements using a built-in motor.

The image processing unit 1405 processes image signals generated by the image sensor 100. This processing includes, for example, assigning a light state to light incident on a pixel 104 by determining ratios of signal strength between pairs of sub-pixels 604 included in the pixel 104, and determining an amplitude of the pixel 104 signal from the individual sub-pixel 604 signal intensities, as discussed elsewhere herein. In addition, this processing includes determining a light state of light incident on a pixel 104 by comparing the observed ratios of signal strengths from pairs of sub-pixels 604 to calibrated ratios for those pairs stored in a calibration table 1004. The image processing unit 1405 can include, for example, a microcomputer equipped with firmware, and/or a processor that executes application programming, to implement processes for identifying color information in collected image information as described herein.

The operation input unit 1406 receives operation inputs from a user of the camera 1400. As the operation input unit 1406, for example, a push button or a touch panel can be used. An operation input received by the operation input unit 1406 is transmitted to the imaging control unit 1403 and the image processing unit 1405. After that, processing corresponding to the operation input, for example, the collection and processing of imaging an object or the like, is started.

The frame memory 1407 is a memory configured to store frames that are image signals for one screen or frame of image data. The frame memory 1407 is controlled by the image processing unit 1405 and holds frames in the course of image processing.

The display unit 1408 can display information processed by the image processing unit 1405. For example, a liquid crystal panel can be used as the display unit 1408.

The recording unit 1409 records image data processed by the image processing unit 1405. As the recording unit 1409, for example, a memory card or a hard disk can be used.

An example of a camera 1400 to which embodiments of the present disclosure can be applied has been described above. The image sensor 100 of the camera 1400 can be configured as described herein. Specifically, the image sensor 100 can diffract incident light across different light sensitive areas or sub-pixels 604 of a pixel 104, and can compare ratios of signals from pairs of the sub-pixels 604 to corresponding stored ratios for a number of different light states, to identify a closest match, and thus the light state of the incident light. Moreover, the color identification capabilities of the image sensor 100 can be described as hyperspectral, as wavelength identification is possible across the full range of wavelengths to which the sub-pixels are sensitive. In accordance with embodiments of the present disclosure, the light states that can be detected include different combinations of wavelength and polarization of incident light. Moreover, polarization states sensitivity can be combined with super resolution, complex field, and wavefront sensitivity.

Note that, although a camera has been described as an example of an electronic apparatus, an image sensor 100 and other components, such as processors and memory for executing programming or instructions and for storing calibration information as described herein, can incorporated into other types of devices. Such devices include, but are not limited to, surveillance systems, automotive sensors, scientific instruments, medical instruments, etc. As further examples, embodiments of the present disclosure can detect the rotation to the polarization of state of light caused by biologically active molecules. In addition, the ability to detect polarization state provided by embodiments of the present disclosure facilitates the encryption of light using polarization state. In accordance with still other embodiments, a system 100 as disclosed herein be implemented in connection with a communication system, in which information is encoded or is distinguished from other units of information using the color and polarization state of light. Still other applications of embodiments of the present disclosure include quantum computing.

As can be appreciated by one of skill in the art after consideration of the present disclosure, an image sensor 100 as disclosed herein utilizes interference effects to obtain light state information, such as wavelength and polarization information, over a wide spectral range. In addition, an image sensor 100 as disclosed herein can be produced using CMOS processes entirely. Implementations of an image sensor 100 or devices incorporating an image sensor 100 as disclosed herein can utilize calibration tables 1004 developed for each pixel 104 of the image sensor 100. Alternatively, calibration tables 1004 can be developed for each different pattern of diffraction features 524. In addition to providing calibration tables 1004 that are specific to particular pixels 104 and/or particular patterns of diffraction features 524, calibration tables 1004 can be developed for use in selected regions of the array 108.

Methods for producing an image sensor in accordance with embodiments of the present disclosure include applying conventional CMOS production processes to produce an array of pixels in an image sensor substrate in which each pixel includes a plurality of sub-pixels or photodiodes. As an example, the material of the sensor substrate is silicon (Si), and each sub-pixel is a photodiode formed therein. A thin layer of material is disposed on or adjacent a light incident side of the image sensor substrate. Moreover, the thin layer of material can be disposed on a back surface side of the image sensor substrate. As an example, the thin layer of material is silicon oxide (SiO₂), and has a thickness of 500 nm or less. In accordance with the least some embodiments of the present disclosure, an anti-reflection layer can be disposed between the light incident surface of the image sensor substrate and the thin layer of material. A light focusing, electrically conductive or semiconductive diffractive grating pattern is formed in the thin layer of material. In particular, a set 524 of diffraction features 528 is disposed adjacent each of the pixels. The diffraction features can be formed as metal or semiconductor material features embedded in trenches formed in the thin layer of material. For example, the diffraction features can be formed from silicon nitride (SiN) or aluminum. Different diffraction features within a set 524 of diffraction features 528 can be formed from different materials. Moreover, the diffraction features 528 can be relatively thin (i.e. from about 100 to about 200 nm), and the pattern can include a plurality of linear diffraction elements 708 of various lengths disposed along lines that extend radially from a central circular feature 704 and scattering elements 712 interspersed between the linear diffraction elements 708. Production of an image sensor in accordance with embodiments of the present disclosure can be accomplished using only CMOS processes. Moreover, an image sensor produced in accordance with embodiments of the present disclosure does not require micro lenses or color filters for each pixel.

The foregoing has been presented for purposes of illustration and description. Further, the description is not intended to limit the disclosed systems and methods to the forms disclosed herein. Consequently, variations and modifications commensurate with the above teachings, within the skill or knowledge of the relevant art, are within the scope of the present disclosure. The embodiments described hereinabove are further intended to explain the best mode presently known of practicing the disclosed systems and methods, and to enable others skilled in the art to utilize the disclosed systems and methods in such or in other embodiments and with various modifications required by the particular application or use. It is intended that the appended claims be construed to include alternative embodiments to the extent permitted by the prior art.

What is claimed is:

1. An image sensor, comprising:
a sensor substrate;
a pixel disposed in the sensor substrate, wherein the pixel includes a plurality of sub-pixels; and
a diffraction layer disposed adjacent a light incident surface side of the sensor substrate, wherein the diffraction layer includes a set of electrically conductive or semiconductive diffraction features.

2. The image sensor of claim 1, wherein the set of diffraction features includes a plurality of linear elements, and wherein at least some of the linear elements in the plurality of linear elements extend along different radii of a circle that is centered at a center point of the pixel.

3. The image sensor of claim 2, wherein the set of diffraction features further includes a plurality of circular elements.

4. The image sensor of claim 1, wherein the set of diffraction features includes a plurality of linear elements, wherein each radial element in the plurality of linear elements extends along different radius of a circle that is centered at a center point of the pixel.

5. The image sensor of claim 4, wherein each of the linear elements extends along a radius of the circle that is spaced apart from a radius along which any neighboring linear element extends by 45 degrees.

6. The image sensor of claim 4, wherein a length of each neighboring linear element in the plurality of linear elements is different.

7. The image sensor of claim 6, wherein, moving in one of a clockwise or an anticlockwise direction from a shortest linear element, a length of a next linear element increases until a longest linear element is reached.

8. The image sensor of claim 3, wherein an area of the diffraction features over any one of the sub-pixels within the pixel is about the same as an area of the diffraction features over any other one of the sub-pixels within the pixel, where about is +/−10%.

9. The image sensor of claim 1, wherein an area of the diffraction features over any one of the sub-pixels within the pixel is about the same as an area of the diffraction features over any other one of the sub-pixels within the pixel, where about is +/−10%.

10. The image sensor of claim 1, wherein the set of diffraction features is electrically conductive.

11. The image sensor of claim 10, wherein the set of diffraction features is formed from a metal.

12. The image sensor of claim 1, wherein at least some of the diffraction features are formed from a first material, and wherein others of the diffraction features are formed from a second material.

13. The image sensor of claim 1, wherein each of the sub-pixels has a first area.

14. The image sensor of claim 1, wherein a plurality of pixels, each including a plurality of sub-pixels, is disposed in the sensor substrate, wherein the plurality of pixels are arranged in a two-dimensional array, and wherein the diffraction layer includes a set of electrically conductive or semiconductive diffraction features for each pixel in the plurality of pixels.

15. The image sensor of claim 14, wherein a pattern of the diffraction features for a first pixel in the plurality of pixels and a diffraction pattern for any of the pixels in the plurality of pixels is the same.

16. The image sensor of claim 1, wherein a wavelength sensitivity of each of the sub-pixels in the pixel is the same.

17. An electronic apparatus, comprising:
an image sensor, including:
a sensor substrate;
a plurality of pixels formed in the sensor substrate, wherein each pixel in the plurality of pixels includes a plurality of sub-pixels, and wherein, for a given pixel in the plurality of pixels, a wavelength sensitivity of each of the sub-pixels is the same; and
a diffraction layer disclosed adjacent a light incident surface side of the sensor substrate, wherein the diffraction layer includes a set of electrically conductive or semiconductive diffraction features for each pixel in the plurality of pixels; and
a processor, wherein the processor executes application programming, wherein the application programming determines a state of light incident on a selected pixel from ratios of a relative strength of a signal generated at each unique pair of sub-pixels of the selected pixel in response to the light incident on the selected pixel.

18. The electronic apparatus of claim 17, further comprising:
an imaging lens, wherein light collected by the imaging lens is incident on the image sensor, and wherein the diffraction features focus and diffract the incident light onto the sub-pixels of the respective pixels.

19. The electronic apparatus of claim 17, further comprising:
data storage, wherein the data storage stores ratios of signal strengths between the sub-pixels of the image sensor pixels for different wavelengths and polarizations of incident light, and wherein different combinations of signal strength ratios identify different wavelengths and polarizations of incident light.

20. A method, comprising:
receiving light at an image sensor having a plurality of pixels;
for each pixel in the plurality of pixels, diffracting the received light onto a plurality of sub-pixels, wherein for each pixel the received light is diffracted by a different set of electrically conductive or semiconductive diffraction features;
for each pixel in the plurality of pixels, determining a ratio of a signal strength generated by the sub-pixels in each unique pair of the sub-pixels; and
determining a light state of the received light at each pixel in the plurality of pixels from the determined ratios of the signal strengths.
